(19) United States
(12) Patent Application Publication
(10) Pub. No.: US 2009/0101497 A1
(43) Pub. Date: Apr. 23, 2009

(54) SPUTTERING SYSTEM CARRIER

(75) Inventor: SEI-PING LOUH, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/170,760

(22) Filed: Jul. 10, 2008

(30) Foreign Application Priority Data
Oct. 23, 2007 (CN) 200710202213.2

(51) Int. Cl. C23C 14/35

(52) U.S. Cl. 204/298.15

(57) ABSTRACT

A sputtering system carrier configured for supporting a workpiece comprises a main body and a supporting body. The main body includes four end to end frames, which are a first frame, a second frame, a third frame, and a fourth frame. The first frame and the third frame each have a sliding slot. The second frame and the fourth frame each has a coil wrapped around the frame. The supporting body includes four end to end frames, which are a fifth frame, a sixth frame, a seventh frame, and an eighth frame. The fifth frame and the seventh frame have a pivot protruding from outside surface. The pivots are movably held in the sliding slots. The pivots are positioned either near the sixth frame or the eighth frame. The sixth frame, the eighth frame, or both have a magnet.

### BACKGROUND

1. Technical Field

The present invention relates to a sputtering system carrier which can overturn automatically to deposit film on two surfaces of a workpiece.

2. Discussion of Related Art

Sputtering is a process whereby atoms are ejected from a solid target material due to bombardment of the target by energetic ions. It is commonly used for thin-film deposition, etching and analytical techniques. The sputtering can be classified into direct current (DC) sputtering and radio frequency (RF) sputtering, depending on the power supply.

The DC sputtering is used when sputtering conductive material, such as Al, Ag, or semiconductor Si. The RF sputtering is used when sputtering insulator material, such as ZnS—SiO₂ or GeSbTe. Sputtering is widely used in industrial manufacturing because a good deposition and a precise control of material can be achieved at a low cost.

Generally, sputtering occurs in a sputter device, which comprises a reaction chamber, at least one sputter cathode, and a carrier. The sputter cathode is set in the reaction chamber and has at least one target. The carrier is configured for transmitting a workpiece to the reaction chamber and supporting the workpiece during sputtering. In the reaction chamber, a glow discharge reaction occurs and generates argon-ion plasma. The argon ions are accelerated by a magnetic field or an electric field and bombard the target. The atoms ejected from the target deposit on the workpiece, forming a film on the workpiece.

After a film is deposited on a first surface of the workpiece, the workpiece is taken out of the reaction chamber and manually flipped over by hand. The workpiece is then taken back into the reaction chamber, and a film is deposited on a second surface opposite to the first surface. This practice wastes time and potentially contaminates the vacuum environment of the reaction chamber.

Therefore, an improved sputtering system carrier is desired to overcome the above-described deficiencies.

### SUMMARY

A sputtering system carrier configured for supporting a workpiece comprises a main body and a supporting body. The main body includes a first frame, a second frame, a third frame opposite to the first frame, and a fourth frame opposite to the second frame. The first frame has a first sliding slot and the third frame has a second sliding slot facing the first sliding slot. The second frame has a first coil set thereon and the fourth frame has a second coil set thereon. The supporting body includes a fifth frame, a sixth frame, a seventh frame opposite to the fifth frame, and an eighth frame opposite to the sixth frame. The fifth frame has a first pivot and the seventh frame has a second pivot. The first pivot is movably held in the first sliding slot and the second pivot is movably held in the second sliding slot. The sixth frame, the eight frame, or both the sixth frame and the eighth frame have a magnet.

### BRIEF DESCRIPTION OF THE DRAWINGS

Many aspects of the present sputtering system carrier can be better understood with reference to the following drawings. The components in the drawings are not necessarily drawn to scale, the emphasis instead being placed upon clearly illustrating the principles of the present sputtering system carrier. Moreover, in the drawings, like reference numerals designate corresponding parts throughout the several views.

FIG. 1 is an assembled, isometric view of an embodiment of a sputtering system carrier;

FIG. 2 is an exploded perspective view of the sputtering system carrier of FIG. 1.

### DETAILED DESCRIPTION OF THE EMBODIMENTS

The embodiments will now be described with reference to the attached drawings.

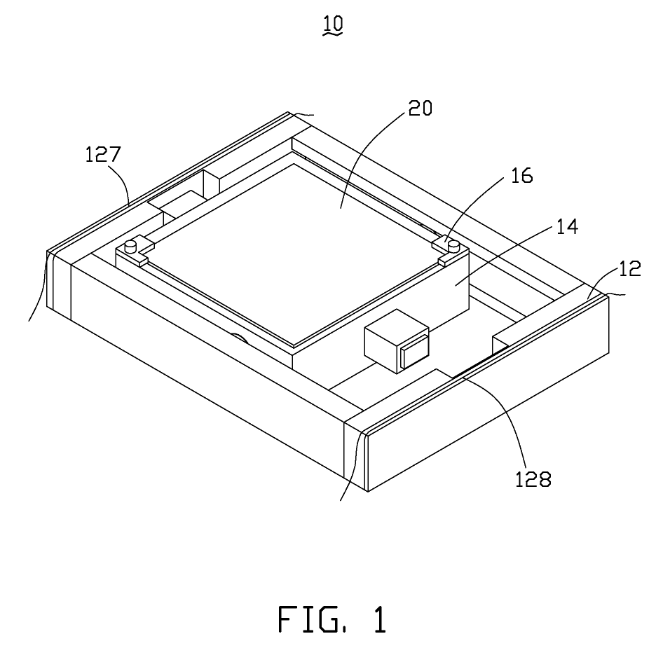

Referring to FIG. 1, a sputtering system carrier 10 includes a main body 12, a supporting body 14, and at least one fixing device 16. A workpiece 20 is fixedly positioned on the supporting body 14 by the fixing device 16 for a sputtering process.

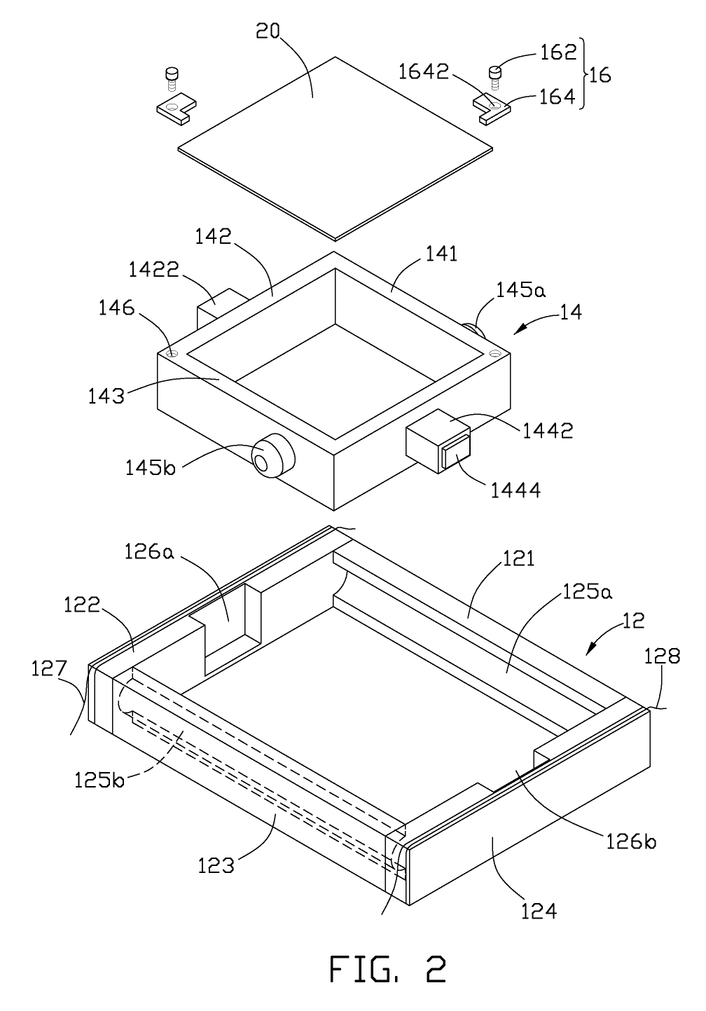

Referring to FIG. 2, the main body 12 includes a first frame 121, a second frame 122, a third frame 123 positioned opposite to the first frame, and a fourth frame 124 positioned opposite to the second frame each frame having connecting end portions. The main body 12 is substantially rectangular-shaped.

A first sliding slot 125a is formed on the first frame 121 and the opening of the first sliding slot 125a faces the third frame 123. A second sliding slot 125b is formed on the third frame 123 and the opening of the second sliding slot 125b faces the first frame 121.

A first locating slot 126a is formed on the second frame 122 facing the fourth frame 124. A second locating slot 126b is formed on the fourth frame 124 facing the second frame 122. The first locating slot 126a and the second locating slot 126b are defined generally in the center of the second frame 122 and the fourth frame 124, respectively.

The second frame 122 and the fourth frame 124 are typically made of Fe—Ni alloy or Fe—Co alloy. Fe—Ni alloy is comprised of 35%˜85% nickel, iron, molybdenum, copper, and tungsten. Fe—Co alloy is a soft magnetic alloy mostly comprised of 27%˜50% cobalt and iron. A first coil 127 is coiled around the second frame 122 and a second coil 128 is coiled around the fourth frame 124. When applying a current through the first coil 127 and the second coil 128, a magnetic field is generated around the first coil 127 and the second coil 128, respectively. The direction of the magnetic field is determined by Ampere's rule or right-hand rule. Under this rule, if the first coil 127 or the second coil 128 is grasped in the right hand in such a way that the fingers curl in the direction of the current, the right thumb points in the direction of the north pole.

The supporting body 14 includes a fifth frame 141, a sixth frame 142, a seventh frame 143 positioned opposite to the fifth frame, and an eighth frame 144 positioned opposite to the sixth frame, each frame having connecting end portions. The supporting body 14 is substantially rectangular-shaped. A size of the supporting body 14 must be able to fit in the main body 12 and slide freely in a direction of the first sliding slot 125a and second sliding slot 125b.

A first pivot 145a protrudes from an outer wall of the fifth frame 141. A second pivot 145b protrudes from an outer wall of the seventh frame 143 and is positioned directly opposite the first pivot. The first pivot 145a and the second pivot 145b are defined in a middle section of the supporting body 14. In the illustrated embodiment, the first pivot 145a and the second pivot 145b are adjacent to the eighth frame 144 such that a distance between the first pivot 145a and the sixth frame 142 is greater than a distance between the first pivot 145a and the eighth frame 144. As a result, the supporting body 14 can rotate about the first pivot 145a and the second pivot 145b. The first pivot 145a and the second pivot 145b are movably held inside the first sliding slot 125a and the second sliding slot 125b, respectively. A distance between the second frame 122 and the fourth frame 124 is at least twice a distance between the first pivot 145a and the sixth frame 142 to allow the supporting body 14 to rotate in the main body 12.

In another embodiment, the first pivot 145a and the second pivot 145b are adjacent to the sixth frame 142.

In one embodiment, the sixth frame 142 has a first locating portion 1422 protruding from an outer wall of the sixth frame 142. The eighth frame 144 has a second locating portion 1442 protruding from an outer wall of the eighth frame 144. A magnet 1444 is fixedly positioned on the second locating portion 1442.

In another embodiment, the magnet 1444 is fixedly positioned on the first locating portion 1422. In yet another embodiment, the magnet 1444 is fixedly positioned on both the first locating portion 1422 and second locating portion 1442.

The supporting body 14 defines at least one first fastener hole on the supporting body 14. In the illustrated embodiment, the first fastener holes 146 are defined on two diagonal corners of the supporting body 14.

Number of the fixing device 16 is equal to that of the first fastener holes 146. Each fixing device 16 includes a fastener 162, such as a screw, and a fixing plate 164. The fixing plate 164 defines a second fastener hole 1642 formed thereon. The fasteners 162 are inserted into the first fastener hole 146 and the second fastener hole 1642 to hold the workpiece 20 in place.

In the illustrated embodiment of FIG. 2, the workpiece 20 is removably fixed to the supporting body 14 and the first locating portion 1422 is engaged in the first locating slot 126a. After the sputtering of a first surface of the workpiece 20 is finished, a current is applied to the second coil 128, and a magnetic field is generated around the second coil 128. An attractive force is generated between the magnet 1444 and the magnetic field. The supporting body 14 slides to the fourth frame 124 under the condition of the attractive force until the second locating portion 1442 is engaged in the second locating slot 126b of the fourth frame 124. The current stops flowing through the second coil 128 and the supporting body 14 rotates 90 degrees under the force of gravity. A current is applied to the first coil 127 and a magnetic field is generated around the first coil 127. An attractive force is generated between the magnet 1444 and another magnetic field. The supporting body 14 gives a 90 degree turn under the condition of the attractive force. A second surface of the workpiece 20 opposite to the first surface is sputtered.

It is to be understood that the above-described embodiment is intended to illustrate rather than limit the invention. Variations may be made to the embodiment without departing from the spirit of the invention as claimed. The above-described embodiments are intended to illustrate the scope of the invention and not restrict the scope of the invention.

What is claimed is:

1. A sputtering system carrier for supporting a workpiece, comprising:
a main body, comprising:
a first frame, wherein the first frame defines a first sliding slot;
a second frame;
a third frame positioned opposite to the first frame, wherein the third frame defines a second sliding slot;
a fourth frame positioned opposite to the second frame;
a first coil coiled around the second frame; and
a second coil coiled around the fourth frame;
a supporting body, comprising:
a fifth frame having a first pivot, wherein the first pivot is movably fixed in the first sliding slot;
a sixth frame;
a seventh frame positioned opposite to the fifth frame having a second pivot, wherein the second pivot is movably fixed in the second sliding slot; and
an eighth frame positioned opposite to the sixth frame;
a magnet fixably attached to one of the sixth frame, the eighth frame, and both the sixth frame and the eighth frame.

2. The sputtering system carrier of claim 1, further comprising a fixing device comprising:
at least one fixing plate;
at least one first fastener hole defined on the supporting body;
at least one second fastener hole defined on the first fixing plate;
at least one fastener; wherein the at least one fastener is engaged with the at least one first fastener hole and the at least one second fastener hole to fix a workpiece on the supporting body.

3. The carrier as claimed in claim 2, wherein a material of the second frame and the fourth frame is selected from the group consisting of Fe—Ni alloy and Fe—Co alloy.

4. The sputtering system carrier of claim 1, wherein the second frame defines a first locating slot; the fourth frame defines a second locating slot; the sixth frame has a first location portion that can engage with the first location slot; the eighth frame has a second locating portion that can engage with the second locating slot; the magnet is set on the one of the first locating portion, the second locating portion, and both the first locating portion and the second locating portion.

5. The sputtering system carrier of claim 4, further comprising a fixing device comprising:
at least one fixing plate;
at least one first fastener hole defined on the supporting body;
at least one second fastener hole defined on the first fixing plate;
at least one fastener; wherein the at least one fastener is engaged with the at least one first fastener hole and the at least one second fastener hole to fix a workpiece on the supporting body.

6. The carrier as claimed in claim 5, wherein a material of the second frame and the fourth frame is selected from the group consisting of Fe—Ni alloy and Fe—Co alloy.

7. The sputtering system carrier of claim 4, wherein the first pivot and the second pivot is near the eighth frame; the first pivot is positioned opposite the second pivot; a distance between the second frame and the fourth frame is at least twice a distance between the first pivot and the sixth frame.

8. The sputtering system carrier of claim 7, further comprising a fixing device comprising:
at least one fixing plate;
at least one first fastener hole defined on the supporting body;
at least one second fastener hole defined on the first fixing plate;
at least one fastener; wherein the at least one fastener is engaged with the at least one first fastener hole and the at least one second fastener hole to fix a workpiece on the supporting body.

9. The carrier as claimed in claim 8, wherein a material of the second frame and the fourth frame is selected from the group consisting of Fe—Ni alloy and Fe—Co alloy.

10. The sputtering system carrier of claim 4, wherein the first pivot and the second pivot is near the sixth frame; the first pivot is positioned opposite the second pivot; a distance between the second frame and the fourth frame is at least twice a distance between the first pivot and the eighth frame.

11. The sputtering system carrier of claim 10, further comprising a fixing device comprising:
at least one fixing plate;
at least one first fastener hole defined on the supporting body;
at least one second fastener hole defined on the first fixing plate;
at least one fastener; wherein the at least one fastener is engaged with the at least one first fastener hole and the at least one second fastener hole to fix a workpiece on the supporting body.

12. The carrier as claimed in claim 11, wherein a material of the second frame and the fourth frame is selected from the group consisting of Fe—Ni alloy and Fe—Co alloy.
